(19) United States
(12) Patent Application Publication
(10) Pub. No.: US 2003/0044726 A1
(43) Pub. Date: Mar. 6, 2003

(54) Method for reducing light reflectance in a photolithographic process

(75) Inventors: Jong Chen, Hsin-Chu (TW); Shyue Sheng Lu, Hsin-Chu (TW); Jyu Horng Shieh, Hsin-Chu (TW)

Correspondence Address: TUNG & ASSOCIATES, 838 W.Long Lake Road, Suite 120, Bloomfield Hills, MI, 48302, US

(73) Assignee: Taiwan Semiconductor Manufacturing Co., Ltd.,

(21) Appl. No.: 09/941,537

(22) Filed: Aug. 29, 2001

(51) Int. Cl. G03F 7/00

(52) U.S. Cl. 430/314; 430/290; 430/313; 430/950

(57) ABSTRACT

A method for reducing light reflectance in photolithographic manufacturing process is disclosed including providing an inter-metal dielectric (IMD) layer including at least one via opening extending substantially perpendicular to a thickness therethrough, and, conformally forming an anti-reflectance coating (ARC) layer over said IMD layer such that the ARC layer is formed over sidewalls of the at least one via opening to reduce light reflectance.

### FIELD OF THE INVENTION

This invention generally involves a method for manufacturing dual damascene structures in semiconductor device manufacturing and more particularly to a method for reducing the effect of light reflectance causing undercutting of a photoresist layer thereby maintaining design distance between metal lines.

### BACKGROUND OF THE INVENTION

Since the introduction of semiconductor devices, the size of semiconductor devices has been continuously shrinking, resulting in smaller semiconductor chip size and increased device density on the chip. One of the limiting factors in the continuing evolution toward the smaller device size and higher density has been the interconnect area needed to route interconnect lines between devices. As a way to overcome such a limitation, multilevel interconnection systems have been implemented using shared interconnect lines between two or more levels.

Originally, conventional process techniques implemented multilevel interconnection systems by depositing a metal layer, photomasking the deposited metal layer, and then etching the metal layer to form desired interconnections. However, since metals are typically more difficult to pattern and etch than other semiconductor layers such as dielectric or oxide layers, a dual damascene process has been implemented to form metal vias and interconnects by dispensing entirely with the metal etching process. The dual damascene process is a well known semiconductor fabrication method for forming metalization vias and interconnect lines.

In the dual damascene process, a via and a trench is etched in an oxide layer such as an inter-metal dielectric layer (IMD). The dielectric layer is typically formed over a metal layer. After a series of photolithographic steps defining via openings and trench openings in an IMD layer, the via and the trench openings are then filled with a metal (e.g., Al, Cu) to form metalization vias and interconnect lines, respectively. The excess metal above the trench level is then removed by well known chemical-mechanical polishing (CMP) processes.

The dual damascene process is gaining wider application in semiconductor processes because it offers significant advantages over the conventional process of etching metals. For example, it does not require etching of metals, such as copper and to a lesser degree, aluminum, which are more difficult to pattern and etch than dielectric materials. Additionally, the dual damascene process involves fewer process steps compared to conventional techniques that form vias in a separate processing step. An additional benefit of a dual damascene is that the metalization via is the same metal as the interconnect line thereby reducing the risk of electro migration failure.

One problem with the dual damascene process, especially where metal interconnect lines are in a head to head design thereby making the distance between metal interconnect lines critical as design rules are scaled down, has been the phenomenon of undercutting the photoresist during a photoresist removal process where portions of a photoresist layer have been unintentionally exposed by scattered or reflected light and are removed after photoresist development. The term “head to head design” is defined as including via openings that are substantially adjacent to one another.

Typically, in a dual damascene manufacturing process known in the art as a via-first-trench last process conventional photolithographic processes using a photoresist layer is first used to pattern and expose an etching mask which is used for etching via openings through the IMD layer. Subsequently a similar process is used to define trench openings that are formed substantially over the via openings which in turn define metallic interconnect lines. the via opening and trench openings are subsequently filled with metal to form metalization vias and metal interconnect lines. The surface may then be planarized by conventional techniques to better define the metal interconnect lines and prepare the substrate for further processing.

During the photolithography process, undercutting the photoresist layer acts to decrease the spacing between metallic lines, compromises device design. As an example of compromised electrical property functionality, the distance between metal interconnect lines may be decreased such that leakage current by a tunneling mechanism may occur. Further, undercutting the photoresist layer acts to weaken the mechanical integrity of the remaining photoresist lines, thereby increasing the possibility of photoresist line failure. In addition, even if the photoresist line doesn't fail, a dielectric insulating material made thinner as a result of undercutting may be structurally weakened and may lead to insulation failure in a resulting semiconductor device. In any case, the integrity of subsequent steps in the dual damascene process are compromised.

As an example, FIG. 1 shows a cross section of a portion of a dual damascene structure at a stage in a dual damascene process of manufacture. Shown in FIG. 1 is an inter-metal dielectric (IMD) 10, typically deposited over a substrate which is not shown. Although there are a number of different dual damascene manufacturing processes, in a typical manufacturing process known in the art as a via-first process, via openings 12a, 12b are formed first in the IMD layer 10. More particularly, a substrate having a first metallic layer is provided (not shown). Next, an IMD layer (10) is formed over the substrate, followed by planarization so that the IMD layer 10 thickness matches the depth of desired via openings 12a, 12b. Thereafter, an etching stop layer (14) is formed over the IMD layer 10. Next, a photoresist layer 16 is formed over the etching stop layer 14, and subsequently patterned as an etching mask. Using the patterned photoresist layer as an etching mask, the etching stop layer 14 and IMD layer 10 are then anisotropically etched to form via openings 12a, 12b through the etching stop layer 14 and IMD layer 10, where the resulting via openings 12a, 12b are in communication with the first metallic layer (not shown).

Typically, an anti-reflectance coating (ARC) layer 15 may be formed over the etching stop layer 14 prior to the conventional photolithographic process used for patterning the via openings 12a, 12b. The ARC layer 15 reduces the effect of light reflection undesirably exposing a photoresist overlayer 16 used for defining via openings 12a, 12b. Light reflection (scattering) from, for example, the IMD layer 10 surface, etching stop layer 14 surface, and their respective interfaces, can cause undesired light exposure of an overlying photoresist layer 16 in a photolithographic masking and patterning steps, for example, in the formation via openings 12a, 12b. As a result, upon development and removal of the exposed photoresist the phenomenon of undercutting (removing photoresist exposed by reflected light in the foot area of the photoresist) will detrimentally affect the design integrity of the manufactured device.

The problem of undercutting a photoresist layer, due to light reflectance has been reduced in some photolithographic processes by the application of ARC layers, yet remains a problem in other photolithographic processes. Specifically, it has been found that the problem of undesired light reflection remains a problem in photolithographic processes following the formation of the via openings. For example, following etching of via openings in a via-first dual damascene manufacturing process, light may scatter from the via sidewalls and edges of an etching stop layer and undesirably expose a subsequent overlayer of photoresist used for masking and patterning trenches for metallic interconnect lines.

At a stage in the dual damascene process, as shown in FIG. 1, photoresist 16 is deposited over the via openings 12a, 12b and etching stop layer 14. The photoresist is then patterned, exposed and developed to define trench openings 18. After formation of trench openings, metal is subsequently deposited in the trench openings and planarized to form metallic interconnect lines.

As shown in FIG. 1, a trench opening 18 remains after the photoresist 16 is exposed to light 20 and the exposed photoresist developed and removed. FIG. 1 shows the exposed photoresist removed for clarity so that one may follow the light exposure and reflectance path 20. Since this photolithographic process is implemented following formation of via openings 12a, 12b, as shown in the FIG. 1, light 20 may now scatter off edges of the etching stop layer 14 and sidewalls 13 of the via openings 12a, 12b, where no ARC layer 15 is present. Consequently, the foot of the photoresist 22 near the via openings is undesirably exposed thereby compromising the trench patterning process. As a result, the photoresist exposed by reflected light from e.g., the via opening sidewalls 13 is undesirably undercut at 22 after development and removal of the photoresist.

Such undercutting acts to reduce the spacing between metal lines subsequently formed from the undercut trenches and may comprise the electrical properties of resulting metal interconnect lines as well as weaken the structural integrity of the remaining masked (unexposed) photoresist. This phenomenon is known in the art as a vertical optical proximity correction (OPC) effect on the metal interconnect line spacing in a dual damascene structure. Frequently, such undercutting may remove from about 10% to about 40% of the width of the masked (unexposed) photoresist. Consequently, such undercutting acts to mechanically weaken the structural integrity of the photoresist, leading to possible failure of the photoresist and thereby the trench pattern.

One solution to the problem of undercutting would be to increase the distance between the trench line patterns or decrease the metal line thickness thereby lessening any mechanical weakening effect due to undercutting. Neither of these proposed solutions, however, are compatible with the trend and necessity of continually-scaling down structure size. Another solution would be apply an ARC layer in such a way to avoid the effect of undesired light scattering and reflections from via edges and sidewalls.

It would therefore be advantageous and a needed solution to the problem presented by the prior art if an ARC layer could be applied in such a way to avoid undesired light scattering off the edges and sidewalls of via openings without imposing restraints that are incompatible with the drive toward smaller scale structures.

### SUMMARY OF THE INVENTION

To achieve the foregoing and other objects, and in accordance with the purposes of the present invention, as embodied and broadly described herein, the present invention provides a method for exposing photoresist in a dual damascene manufacturing process with reduced light reflectance.

According to a first embodiment, the present invention provides a method for reducing light reflectance in a photolithographic process, including providing an inter-metal dielectric (IMD) layer including at least one via opening extending substantially perpendicular to a thickness therethrough; and, conformally forming an anti-reflectance coating (ARC) layer over said IMD layer such that the ARC layer is formed over sidewalls of the at least one via opening to reduce light reflectance.

In a related embodiment according to the present invention, prior to the step of conformally forming an ARC layer an etching stop layer is formed over said IMD layer, and a first anti-reflectance coating (ARC) layer is formed over said etching stop layer.

In other related embodiments according to the present invention, the etching stop layer and the ARC may include silicon oxynitride. Alternatively, the etching stop layer may include silicon nitride and the ARC may include silicon oxynitride. Alternatively, the ARC may include titanium nitride.

In another related embodiment according to the present invention, in the step of conformally forming an anti-reflectance coating (ARC) layer over said IMD layer such that the ARC layer is formed over sidewalls of the at least one via opening to reduce light reflectance, further comprises a subsequent photolithographic process including formation of trench openings substantially over the at least one via opening.

In another related embodiment, the present invention provides a method including providing an inter-metal dielectric (IMD) layer including at least one via opening extending substantially perpendicular to a thickness therethrough; and conformally forming an anti-reflectance coating (ARC) layer over said IMD layer such that the ARC layer is formed over sidewalls of the at least one via opening to reduce light reflectance, the said at least one via opening includes at least two via openings formed substantially adjacent to one another.

In another related embodiment, the present invention further includes an ARC layer formed within a range of thickness from about 100 Angstroms to about 1000 Angstroms.

In a second embodiment according to the present invention, a method is provided for reducing an undercutting effect in a photoresist layer in a photolithographic process including providing an inter-metal dielectric (IMD) layer said IMD layer further including via openings extending through said IMD layer; conformally forming an anti-reflectance coating (ARC) layer over said IMD layer and said via openings; and, forming a photoresist layer over said IMD layer and photolithographically exposing a pattern defining trench openings disposed at least partially over said via openings.

In a third embodiment according to the present invention, an improved method is provided for reducing light reflectance in a dual damascene structure, the method including forming a first dielectric layer on an underlying substrate; forming at least one dielectric layer over said first dielectric layer; forming at least one anti-reflectance coating (ARC) layer over the at least one dielectric layer; forming at least one via opening substantially through the ARC layer, the at least one dielectric layer, and the first dielectric layer; forming at least one additional ARC layer substantially conformally over the at least one ARC layer and the at least one via opening; forming a layer of photoresist over the at least one additional ARC layer; and exposing selected regions of the layer of photoresist layer to light such that the light penetrates the layer of photoresist and is at least partially absorbed by the at least one additional ARC layer and the at least one ARC layer.

### BRIEF DESCRIPTION OF THE DRAWINGS

FIG. 1 is a cross-sectional view according to the prior art of a portion of a dual damascene structure shown at a stage of a via-first dual damascene manufacture process.

FIG. 2 is a cross-sectional view of a portion of a dual damascene structure including a conformally applied ARC layer according to the present invention.

FIG. 3 is a cross-sectional view according to the present invention of a portion of a dual damascene structure shown at a stage of a via-first dual damascene manufacture process.

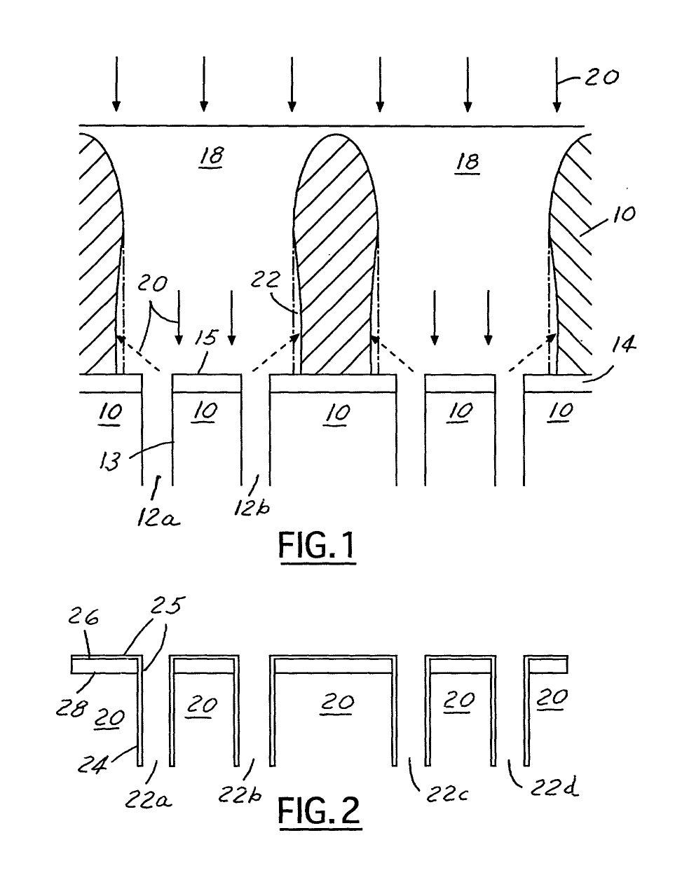

### DETAILED DESCRIPTION OF THE PREFERRED EMBODIMENTS

According to a first embodiment of the present invention, there is provided a method including providing an inter-metal dielectric (IMD) layer including at least one via opening extending substantially perpendicular to a thickness therethrough; and, conformally forming an anti-reflectance coating (ARC) layer over said IMD layer such that the ARC layer is formed over sidewalls of the at least one via opening to reduce light reflectance.

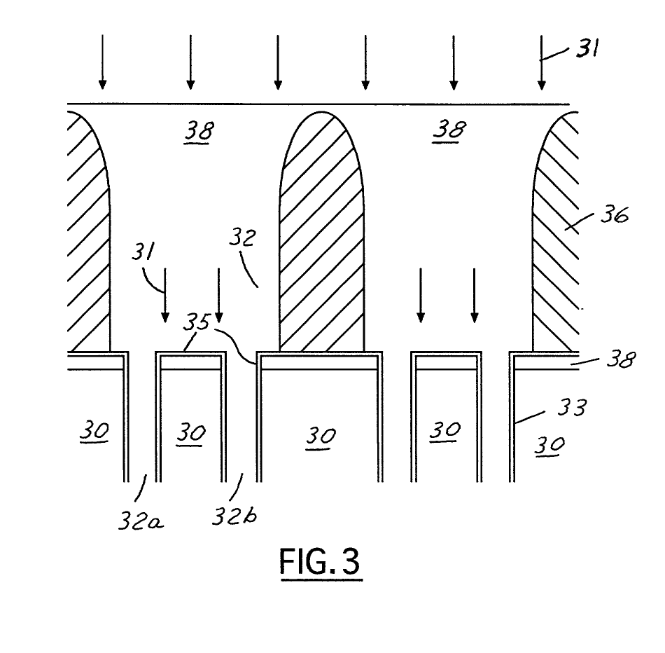

FIG. 2 is a cross-sectional view of a portion of a dual damascene structure shown at a stage of processing. As shown in FIG. 2, according to a first embodiment of the resent invention, an inter-metal dielectric (IMD) layer 20 is shown as a portion of a dual damascene structure including via openings 22a, 22b, 22c, 22d extending substantially perpendicular to a thickness therethrough.

The IMD layer 20 is formed of the dielectric materials such as silicon nitride, silicon oxide (such as PE oxide, fluoride silicate glass (FSG), PSG, BSG, PBSG, TEOS oxide, etc.), low k materials such as black diamond, SILK, CORAL, etc.

When layered structures are discussed with reference to FIG. 2, they can be presumed to extend over the cross section of dual damascene structure shown in FIG. 2. An etching stop layer 28, as in one embodiment is shown deposited over the IMD layer 20, and a first anti-reflectance coating (ARC) layer 26 according to another embodiment is be formed over said etching stop layer 28.

Further, a conformally deposited ARC layer 25 according to the present invention is formed over the sidewalls 24 of the via openings.

According to one embodiment, prior to the step of conformally forming an ARC layer 25 over the IMD layer 20, an etching stop layer 28 is formed over the IMD layer 20, and a first anti-reflectance coating (ARC) layer 26 is formed over the etching stop layer 28. By the term conformally formed, it is intended that the ARC layer 25 is formed over the tops (e.g., etching stop layer 28 as well as the sidewalls 24 of the via openings 22a, 22b, 22c, 22d.

In related embodiments, the etching stop layer 28 and the overlying ARC layer 26 may include the same material, silicon oxynitride. The silicon oxynitride etching stop layer 28 not only protects the IMD layer 20 against etching by oxygen plasma, it also acts as an anti-reflective coating (ARC) layer in subsequent deep ultra violet (DUV) photolithographic operations. The silicon oxynitride etching stop layer has a thickness of about 100 to about 1000 Angstroms.

Alternatively, the etching stop layer 28 may include silicon nitride and the ARC 26 may include silicon oxynitride. In another embodiment, the ARC 26 may include titanium nitride.

The material of the ARC is selected depending on the wavelength of the light source used during the photoresist exposure step for the damascene patterning. For example, titanium nitride (TiN) is a preferable ARC material for an I-line source, and silicon oxynitride (SiON) is preferable for a deep ultra-violet (DUV) source.

The preferred deposition method for ARC 22 is a PECVD process. Although such a deposition processes is preferred, it will be appreciated by the skilled artisan that the ARC 22 may be deposited using any suitable deposition processes such as CVD, PVD, and sputter deposition processes.

The thickness of the ARC may be deposited within a range of about 100 Angstroms to about 1000 Angstroms depending on the desired anti-reflectance properties of the ARC as will be readily appreciated by those skilled in the art. Further, the anti-reflectance coating (ARC) may comprise either an organic or inorganic material although an inorganic material is preferred.

FIG. 3 is a cross-sectional view of a portion of a dual damascene structure at a stage of manufacture. The discussion above with respect to FIG. 2 generally applies to FIG. 3 as well. FIG. 3 depicts a stage of manufacture following the formation of a first dielectric layer 30 on an underlying substrate (not shown); forming at least one dielectric layer (e.g., 38) over said first dielectric layer; forming at least one anti-reflectance coating (ARC) layer (e.g., 36) over the at least one dielectric layer; forming at least one via opening (e.g. 32a, 32b) substantially through the ARC layer 36, the at least one dielectric layer 38, and the first dielectric layer 38, the at least one via opening 32a, 32b; forming at least one additional ARC layer 35 substantially conformally over the at least one ARC layer 36 and the at least one via opening 32a, 32b); forming a layer of photoresist 36 over the at least one additional ARC layer 35; and, exposing selected regions of the layer of photoresist layer to light such that the light penetrates the layer of photoresist and is at least partially absorbed by the at least one ARC layer (36) and the at least one additional ARC layer 35.

As shown in FIG. 3, conformal application of an additional ARC layer (applied over via opening sidewalls 33) following formation of the via openings serves to reduce light reflections, thereby minimizing the effect of undercutting. According to the present invention, as shown in FIG. 3, undercutting of the photoresist in the foot area of the resist at 32 is reduced or eliminated.

The photoresist layer 36 serving to define the trench opening pattern 38 is preferably from 1000 to 20000 Angstroms. It will further be appreciated by those skilled in the art that positive photoresist is the preferable photoresist.

It will further be appreciated that the above process steps with respect to any of the embodiments according to the present invention can be repeated in succession a plurality of times in order to fabricate multiple levels of via metallizations and metallic interconnects to form multi-level ULSI circuits.

While the embodiments illustrated in the Figures and described above are presently preferred, it should be understood that these embodiments are offered by way of example only. Other embodiments may include; for example, the use of more than one anti-reflectance coating with similar processing steps. The invention is not limited to a particular embodiment, but extends to various modifications, combinations, and permutations that nevertheless fall within the scope of the appended claims.

What is claimed is:

1. A method for reducing light reflectance in a photolithographic process, the method comprising the steps of:
providing a substrate having an inter-metal dielectric (IMD) layer on top including at least one via opening extending substantially perpendicular to a thickness therethrough; and
conformally depositing an anti-reflectance coating (ARC) layer over said IMD layer such that the ARC layer is formed over sidewalls of the at least one via opening to reduce light reflectance.

2. The method according to claim 1, wherein prior to the step of conformally depositing an ARC layer an etching stop layer is formed over said IMD layer, and a first anti-reflectance coating (ARC) layer is formed over said etching stop layer.

3. The method of claim 2, wherein the etching stop layer comprises silicon oxynitride.

4. The method of claim 1, wherein the ARC layer comprises silicon oxynitride.

5. The method of claim 2, wherein the ARC layer comprises silicon oxynitride.

6. The method of claim 2, wherein the etching stop layer comprises silicon nitride.

7. The method of claim 1, wherein the ARC layer is selected from the group consisting of at least one of silicon oxynitride and titanium nitride.

8. The method of claim 1, wherein the ARC layer is formed within a range of thickness from about 100 Angstroms to about 1000 Angstroms.

9. The method of claim 1, further comprising a subsequent photolithographic process including formation of trench openings substantially over the at least one via opening.

10. The method of claim 1, wherein said at least one via opening includes at least two via openings formed substantially adjacent to one another.

11. A method of reducing an undercutting effect in a photoresist layer in a photolithographic process comprising the steps of:
providing a substrate having an inter-metal dielectric (IMD) layer on top, said IMD layer further comprising via openings extending through said IMD layer;
conformally forming an anti-reflectance coating (ARC) layer over said IMD layer and said via openings; and
forming a photoresist layer over said IMD layer and photolithographically exposing a pattern defining trench openings disposed at least partially over said via openings.

12. The method of claim 11, wherein the ARC layer comprises a second ARC layer conformally formed at least partially over a first ARC layer following formation of said via openings, said first ARC layer having been formed over the IMD layer prior to formation of said via openings.

13. The method of claim 11, wherein prior to forming the ARC layer, an etching stop layer is formed over the IMD layer.

14. The method of claim 13, wherein the etching stop layer comprises silicon oxynitride.

15. The method of claim 11, wherein the ARC layer is selected from the group consisting of at least one of silicon oxynitride and titanium nitride.

16. The method of claim 12, wherein the ARC layer comprises silicon oxynitride.

17. The method of claim 11, wherein the ARC layer is formed within a range of thickness from about 100 Angstroms to about 1000 Angstroms.

18. The method of claim 11, wherein said via openings are formed substantially adjacent to one another.

19. The method of claim 11, further comprising repeating said method as part of a manufacturing process to form a multi-level interconnected semiconductor structure.

20. A improved method of reducing light reflectance in a dual damascene structure, the method comprising the steps of:
forming a first dielectric layer on an underlying substrate;
forming at least one dielectric layer over said first dielectric layer;
forming at least one anti-reflectance coating (ARC) layer over the at least one dielectric layer;
forming at least one via opening substantially through the ARC layer, the at least one dielectric layer, and the first dielectric layer;
forming at least one additional ARC layer substantially conformally over the at least one ARC layer and the at least one via opening;
forming a layer of photoresist over the at least one additional ARC layer; and
exposing selected regions of the layer of photoresist layer to light such that the light penetrates the layer of photoresist and is at least partially absorbed by the at least one additional ARC layer and the at least one ARC layer.
